(19) United States
(12) Patent Application Publication
(10) Pub. No.: US 2025/0071954 A1
(43) Pub. Date: Feb. 27, 2025

(54) Passive Flow Control for Thermal Management of Hardware Components

(71) Applicant: Seguente, Inc., Melbourne, FL (US)

(72) Inventors: Ryan Enright, Berkeley Heights, NJ (US); Alexei Tyryshkin, Palm Bay, FL (US); John Kim, Orlando, FL (US); Raffaele Luca Amalfi, Melbourne, FL (US)

(21) Appl. No.: 18/944,657

(22) Filed: Nov. 12, 2024

Related U.S. Application Data
(63) Continuation-in-part of application No. 18/209,752, filed on Jun. 14, 2023.
Application No. 18/209,752 is a continuation-in-part of application No. 18/198,522, filed on May 17, 2023.
(60) Provisional application No. 63/599,107, filed on Nov. 15, 2023.
(60) Provisional application No. 63/352,224, filed on Jun. 15, 2022.
(60) Provisional application No. 63/344,291, filed on May 20, 2022.

(51) Int. Cl. H05K 7/20

(52) U.S. Cl. CPC H05K 7/20836; H05K 7/20772

(57) ABSTRACT

Apparatus, devices, systems, subsystems and methods for passively balancing and controlling coolant flow throughout complex fluidic pipe network to be implemented in electronics cooling applications. Systems, sub-systems, devices and methods for providing cooling to hardware components, and more specifically to control flow distribution between sub-systems, devices and methods for thermal management of hardware in server racks and any other hardware components or equipment for the information and communications technology (ICT) industry.

### CROSS REFERENCE TO RELATED APPLICATIONS

This application, which claims the benefit of priority to U.S. Provisional Patent Application Ser. No. 63/599,107 filed Nov. 15, 2023. This application is a Continuation-In-Part of U.S. patent application Ser. No. 18/209,752 filed Jun. 14, 2023, which claims the benefit of priority to U.S. Provisional Patent Application Ser. No. 63/353,224 filed Jun. 17, 2022. U.S. Patent application Ser. No. 18/209,752 filed Jun. 14, 2023 is a Continuation-In-Part of U.S. patent application Ser. No. 18/198,522 filed May 17, 2023 which claims the benefit of priority to U.S. Provisional Application Ser. No. 63/344,291 filed May 20, 2022. The entire disclosure of each of the applications listed in this paragraph are incorporated herein by specific reference thereto.

### FIELD OF INVENTION

This invention relates to systems, sub-systems, devices and methods for providing cooling to hardware components, and more specifically to flow distribution control sub-systems, devices and methods for thermal management of hardware in server racks and any other hardware components or equipment for the Information and communications technology (ICT) industry.

### BACKGROUND AND PRIOR ART

The seismic shift towards digitization across virtually all industries is resulting in urgent mandates to develop next generation ICT (Information and Communication Technology) to address transmission, orchestration, storage, and processing of evermore increasing volume of data. It is widely expected that, due to the higher power dissipation of new generations of hardware components, e.g., CPUs (Central Processing Units) and GPUs (graphical processing units), traditional air-based thermal management solutions will face significant challenges. Specifically, air-cooling technologies will likely reach physical limits for power dissipation in prevailing hardware form factors and their decreasing energy efficiency is a growing concern.

Most data centers and telecom installations are designed for and still operate with air-cooling technologies, and their energy consumption to cool hardware equipment is on average approximately 35 to approximately 40% of the total energy consumption.

With growing awareness of social responsibility to combat climate change, there is a global consensus for action to improve energy efficiency and reduce carbon emissions across all the ICT market segments. Hence, it is extremely important the development of a novel high-efficiency cooling technology, which will meet these requirements and can be widely adopted.

Liquid cooling technologies provide excellent key metrics, e.g., heat density, efficiency, reliability, etc., and represent a viable, long-term solution with regards to hardware densifications and thermal performance required by next generation telecommunications and computing platforms.

In liquid cooling thermal management systems, the coolant is routed via conduits into the server to one or more cold plates in which the coolant extract heat from the hardware components via sensible heat or latent heat, depending if the cooling implementation is based on single-phase or two-phase approach. The resulting coolant is then routed back out of the server to a heat rejection unit that rejects heat to a secondary side medium to repeat the cycle.

In general, server architectures present as a highly constrained design space for fluid routing which has an impact on the size and layout of fluid conduits as well as cold plate design. These constraints require the designer to consider the combination of the fluid conduit routing and cold plates as a sub-system of the cooling system, collectively termed the cold-plate loop (CPL) here, to be optimized in order to meet the required performance goals in terms of thermal resistance, uniform cooling and overall CPL pressure drop.

This invention details direct liquid cooling (DLC) flow distribution architectures addressing multiple heat sources to ensure optimal operation of liquid cooling technologies overcoming flow instabilities, flow maldistribution and extending IT (Information Technology) hardware lifetime.

U.S. Pat. No. 9,655,282 to Barringer et al., which is incorporated by reference presents a method for adjusting coolant flow resistance through one or more liquid-cooled electronics racks. Flow restrictors are employed in association with multiple heat exchange tube sections of a heat exchange assembly, or in association with a plurality of coolant supply lines or coolant return lines feeding multiple heat exchange assemblies. Flow restrictors associated with respective heat exchange tube sections (or respective heat exchange assemblies) are disposed at the coolant channel inlet or coolant channel outlet of the tube sections (or of the heat exchange assemblies). These flow restrictors tailor coolant flow resistance through the heat exchange tube sections or through the heat exchange assemblies to enhance overall heat transfer within the tube sections or across heat exchange assemblies by tailoring coolant flow. In one embodiment, the flow restrictors tailor a coolant flow distribution differential across multiple heat exchange tube sections or across multiple heat exchange assemblies. The authors describe the use of fixed orifices, manually adjustable orifices and active adjustable orifices refrigerant flow control valves.

US Published Patent Application 2021/0368656 to Heydari, which is incorporated by reference, disclose a data center cooling system including one or more flow controllers within a rack manifold, a server manifold, or server tray to facilitate movement of a coolant associated with a secondary cooling loop to cool a component within a server in response to the component monitoring its internal temperature. The cooling system further comprises a learning subsystem comprising at least one processor for evaluating internal temperatures of one or more components within the server with flow rates associated with the one or more flow controllers, and for providing an output associated with a flow rate for facilitating the movement of the coolant by controlling the one or more flow controllers.

Thus, the need exists for solutions to the problems with the prior art.

### SUMMARY OF THE INVENTION

The prior art does not teach or generally suggest how to address the fundamental challenge of fluid distribution in a fully optimized, fully adaptable multi-heat-source liquid-cooling thermal management systems for information and communication technology (ICT) hardware. This challenge encompasses both passive/active two-phase cooling and active single-phase cooling solutions.

A primary objective of the subject invention is to provide systems, sub-systems, devices and methods for mitigating the effects of working fluid maldistribution in a flow distributing manifold due to static head variation along the elevation of a rack, cabinet or any other mounting structure and fluid flow inertial effects.

A secondary objective of the subject invention is to provide systems, sub-systems, devices and methods for generally mitigating the effects of working fluid maldistribution to multiple cold plates arranged fluidically in parallel due to static and dynamic flow path impedance variations.

A third objective of the subject invention is to provide systems, sub-systems, devices and methods for facilitating agnostic deployment of cold plates and fluid routing in a server and then that server into an arbitrary position in the mounting structure.

Balancing flow to multiple flow paths in parallel presents as a challenge in system design and operation. An ideal solution can be achieved in a passive manner that does not require active feedback control in the deployed system to maximize reliability and minimize cost.

Considering this goal, the ideal flow control apparatus will be one that utilizes a fluid-structure interaction mechanism to allow for a constant or substantially constant mass flow rate within a design range to be achieved regardless of pressure drop across the apparatus and without external intervention. The apparatus should be designed with a compact form factor to deliver the requisite amount of mass flow to meet the a priori thermal design power (TDP) needs of a device to be cooled in order to solve the technical challenge to flexibly deploying complex fluidic networks with a multitude of discrete heat sources in modern and future ICT hardware.

Constant flow control valves (CFCVs) are designed to maintain a preset design flow rate in a flow line that may be subject to upstream or downstream pressure fluctuations. This is particularly relevant for ICT liquid cooling systems where the pressure drop characteristics across the cold plates vary considerably depending on the amount of heat being dissipated due to the non-linear pressure drop as a function of mass flow rate in single and two-phase flow and, additionally, as a function of vapor quality in two-phase flow.

A further challenge in two-phase cooling systems designed for cooling server racks is the variation of the static pressure gradient along the elevation of the rack due to gravity and the fluid density imbalance between the liquid supply line and the liquid/vapor mixture return line. This challenge is further exacerbated by the highly dynamic nature of heat dissipation from a server or any other IT equipment. The amount of heat, Q, advected away from a heat source by a flow is proportional to the mass flow rate of the coolant, Q∝m.

In single phase flow the response to heat absorption is a change in the temperature of the fluid given by ΔT=Q/(\dot{m}Cₚ), where Cₚ is the working fluid specific heat capacity at constant pressure.

For two-phase flows, the response to heat absorption is a change in flow quality (the portion of the total mass flow that is in the vapor phase), Δx=Q/(\dot{m}hᵢᵥ), where hₗᵥ is the working fluid's latent heat of vaporization.

Ensuring that a sufficient amount of flow is distributed to the various heat sources to achieve a design ΔT in single phase flow and Δx in two-phase flow under prescribed heat dissipation levels is a key requirement in the system implementation. Thus, there is a need for a solution which can achieve the necessary flow control in a reliable, efficient, and low complexity way. Passive CFCVs that can automatically respond to varying pressure conditions in the system can solve the challenge of flow maldistribution in single-phase and two-phase cooling systems applied to server racks or to any other IT systems or sub-systems.

In this disclosure, it is described where CFCVs are deployed in the cooling system as well as specific implementations of compact CFCVs suitable for IT systems and sub-systems.

Further objects and advantages of this invention will be apparent from the following detailed description of the presently preferred embodiments which are illustrated schematically in the accompanying drawings.

### BRIEF DESCRIPTION OF THE FIGURES

The drawing figures depict one or more implementations according to the present concepts, by way of example only, not by way of limitations. In the figures, same embodiments are indicated with the same reference numerals.

FIG. 1 shows an idealized constant flow control valve (CFCV) response curve in terms of the fluid mass flow rate as a function of the pressure drop across the CFCV.

FIG. 2a shows a summary of data for a two-phase rack cooling system's flow distribution characteristic in terms of individual server mass flow rate before and after implementing CFCVs at the server level.

FIG. 2b shows a summary of data for a two-phase rack cooling system's flow distribution characteristic in terms of individual server exit flow quality before and after implementing CFCVs at the server level.

FIG. 3 shows a schematic of an embodiment of a dual socket cold plate loop (CPL) implementation in a serial flow configuration with an inline CFCV on the liquid supply side.

FIG. 4 shows a schematic of an embodiment of a dual socket CPL implementation in a parallel flow configuration with two inline CFCV's on the liquid supply side.

FIG. 5 shows a schematic of an embodiment of a dual socket CPL implementation in a parallel flow configuration with CFCVs integrated in the liquid supply ports of the cold plates.

FIG. 6 shows a schematic of an embodiment of a CPL implementation in a hybrid serial/parallel flow configuration with CFCV elements only integrated in the cold plates whose inlets are fed by the liquid supply line.

FIG. 7 shows a schematic of an embodiment of a CPL implementation in an arbitrary parallel flow configuration with CFCVs integrated in the cold plates.

FIG. 8a shows a schematic of an embodiment of an ortho-planar spring orifice plate CFCV device in the housing.

FIG. 8b shows a schematic of an embodiment of an ortho-planar spring orifice plate embodiment.

FIG. 8c shows a schematic of an embodiment of an ortho-planar spring orifice plate CFCV design in the equilibrium (no flow) position.

FIG. 8d shows a schematic of an embodiment of an ortho-planar spring orifice plate CFCV design in the maximum forward flow position.

FIG. 8e shows a schematic of an embodiment of an ortho-planar spring orifice plate CFCV design in the maximum reverse flow position.

FIG. 9a shows an ortho-planar spring orifice plate CFCV force-displacement curve.

FIG. 9b shows an ortho-planar spring orifice plate CFCV effective spring stiffness-force curve.

FIG. 9c shows an ortho-planar spring orifice plate CFCV design flow response behavior.

FIG. 10a shows a schematic of an embodiment of the CFCV incorporated into the cover of a cold plate.

FIG. 10b shows a cross-section schematic of the CFCV incorporated into the cover of a cold plate.

FIG. 11 shows a schematic of an embodiment of a compact variable flow area CFCV incorporating an ortho-planar spring.

FIG. 12 shows a schematic of an embodiment of a compact variable flow area CFCV incorporating a wave spring.

FIG. 13 shows a schematic of an embodiment of a spring cantilever-based CFCV integrated into the cold plate cover.

FIG. 14 shows a schematic of an embodiment of a double spring cantilever-based flow control valve integrated into the cover of a cold plate.

FIG. 15 shows a schematic of an embodiment of a two-stage cantilever spring for flow control that mitigates cavitation in the control region.

FIG. 16 shows a schematic of an embodiment of a cantilever spring for flow control and low stiffness cantilever spring check valve.

FIG. 17 shows a schematic of an embodiment of a pumped centralized Coolant Distribution Unit (CDU) supplying multiple racks with coolant, implementing rack-scale CFCVs on the rack liquid supply lines.

FIG. 18 shows a schematic of an embodiment of a passive centralized Coolant Distribution Unit (CDU) supplying multiple racks with coolant, implementing rack-scale CFCVs on the rack liquid supply lines.

### DESCRIPTION OF THE PREFERRED EMBODIMENTS

Before explaining the disclosed embodiments of the present invention in detail, it is to be understood that the invention is not limited in its applications to the details of the particular arrangements shown since the invention is capable of other and more general embodiments. Also, the terminology used herein is for the purpose of description and not of limitation. In the sections named Summary of the Invention and Description of Preferred Embodiments, including the accompanying drawings, reference is made to particular features and method steps of the invention. It is to be understood that the disclosure of the invention in this specification does not include all possible combinations of such particular features. For example, where a particular feature is disclosed in the context of a particular aspect or embodiment of the invention, that feature can also be used, to the extent possible, in combination with and/or in the context of other particular aspects and embodiments of the invention, and in the invention generally.

In this section, some embodiments of the invention will be described more fully with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will convey the scope of the invention to those skilled in the art. Like numbers refer to like elements throughout, and prime notation is used to indicate similar elements in alternative embodiments.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise specifically noted, articles depicted in the drawings are not necessarily drawn to scale.

### LIST OF ABBREVIATIONS

CDU Coolant Distribution Unit
CFCV Constant flow control valve
CPL cold plate loop
CPU central processing unit
CSA cross section area
GPU graphical processing unit
ICT Information & Communication Technology
ITE Information Technology Equipment
TDP thermal design power

### A List of Components Will Now be Described

300 schematic of a dual socket cold plate loop (CPL) implementation with an inline CPL CFCV in a serial flow configuration.
301 liquid flows
302 two inline CFCVs
302 Inline constant flow control valve
303, 304 cold plates
305 two-phase return side
306 two-phase flow to manifold
400 schematic of a dual socket cold plate loop (CPL) implementation with two line CPL CFCV.S in parallel flow configuration
401 branch point
402 two-phase mixture from each cold plate recombines
500 dual socket cold plate loop (CPL) implementation in a parallel configuration with CFCVs integrated in the liquid supply ports of the cold plate
501 two integrated constant flow control valves
502, 503 two cold plates
600 schematic of a cold plate loop (CPL) implementation in a hybrid serial/parallel flow configuration with CFCVs integrated in only the cold plates whose inlets are fed by the liquid supply line
601 cold plate without CFCV
700 schematic of cold plate loop (CPL) implementation in an arbitrary parallel flow configuration with CFCVs integrated in the cold plate
701 local parallel flow distribution manifold
800 schematic of an ortho-planar spring orifice plate CFCH embodiment
801 sprung orifice plate
802 supporting structure (body)
803 support structure (body)
804 fixed orifice dimensions
805 variable gap between the orifice plate and the bottom insert
1000 schematic of the CFVC incorporated into the cold plate cover
1001 recess
1002 cover plate
1003 retaining ring
1004 deformable element
1005 shaped flow opening
1006 cold plate manifold
1007 cold plate heat transfer base
1100 schematic of a compact variable low area CFCV embodiment
1101 high stiffness linear ortho-planar spring
1102 cylindrical body
1103 variable orifice flow area
1104 displacement vector
1105 fixed concentric cylinder
1106 cold plate inlet manifold
1200 schematic of an additional embodiment of a compact variable flow area CFCV
1201 high stiffness linear compression wave spring
1202 cylindrical body
1203 variable orifice flow area
1300 schematic of an embodiment of a spring cantilever-based CFCV integrated into the cold plate cover
1301 linear low stiffness cantilever spring
1302 liquid inlet manifold of the cover plate
1303 inlet port
1304 cover plate
1305 low pressure side of liquid manifold
1306 pre-tensioning support structure
1307 support structure to control spring effective stiffness
1400 schematic of an embodiment of a double spring cantilever-based flow control valve integrated into the cold plate cover
1401 liquid entering the cold plate
1402 cantilever spring pair
1403 heat transfer section
1500 schematic of a two-stage cantilever spring for flow control that manages the risk of cavitation in the control region
1502 first cantilever-based valve
1503 second cantilever-based valve
1504 vena contracta region
1600 schematic of a cantilever spring for flow control and low stiffness cantilever spring check valve
1601 inlet port
1602 low stiffness cantilever spring
1700 schematic of a centralized pumped coolant distribution unit (CDU) supplying multiple racks with coolant implementing rack-scale (CFCVs as safety devices on the rack liquid supply line
1701 pumped CDU
1702 overhead manifold
1703 multiple racks
1704 rack manifold
1705 heat generating components
1706 local CFCVs
1707 rack-scale CFCV
1708 non-return valve
1800 schematic of a centralized passive coolant distribution unit (CDU) supplying multiple racks with coolant implementing rack-scale (CFCVs as safety devices on the rack liquid supply line
1801 CDU
1802 elevated distance

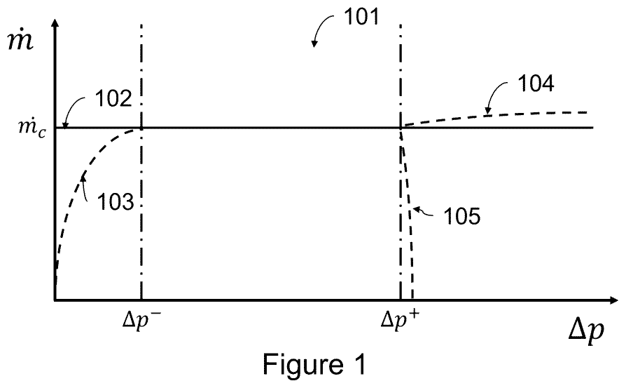

FIG. 1 shows an idealized constant flow control valve (CFCV) with its characteristic curve, expressed in terms of mass flow rate as a function of pressure drop. A CFCV controls the flow of a fluid based on the principle of fluid-structure interaction. As the pressure difference across the valve structure, Δp, increases, the flow conduit defined by the valve structure becomes progressively restricted.

Through careful design, the mass flow can be made constant or substantially constant as the pressure differential across the valve structure varies. Typically, there is a range of pressure differentials across the CFCV (101) where the mass flow rate can be controlled to a design value, \dot{m}_{c} (102). At the low end (≤Δp⁻), the force acting on the flow control element is insufficient to actuate the valve mechanism resulting in a fixed but large flow coefficient (Cv) such that the flow rate is increasing with increasing pressure drop at a fast rate (103). At the other end of the control range (Δp⁺), the displacement of the flow control element is at its maximum resulting in either a fixed, but small Cv such that the flow rate begins to increase again with increasing pressure drop albeit at a smaller rate (104) or the flow is completely closed off (105).

The design mass flow rate is selected based on the requirements of the cooling target. For example, a processor will be designed with a maximum thermal design power (TDP) which is known a priori to the thermal management system designer. Thus, for a single-phase cooling system the design mass flow rate for a heat sink cooling the processor will be given by \dot{m}_{c}=TDP/(CPAT) and, for a two-phase cooling system, by \dot{m}_{c}=TDP/(hl,Δx), where Cₚ is the specific heat capacity of the working fluid, ΔT is the design temperature rise of the working fluid as it absorbs heat, hₗᵥ is the latent heat of vaporization of the working fluid, and Δx is the design quality change of the working fluid as it absorbs heat.

The CFCV is designed to operate in a wide range of differential pressures across the valve, specifically to achieve the design mass flow rate at a minimum pressure differential and to control the mass flow rate up to, at least, a pressure differential defined by the maximum pump head or static gravitational head in the liquid cooling system.

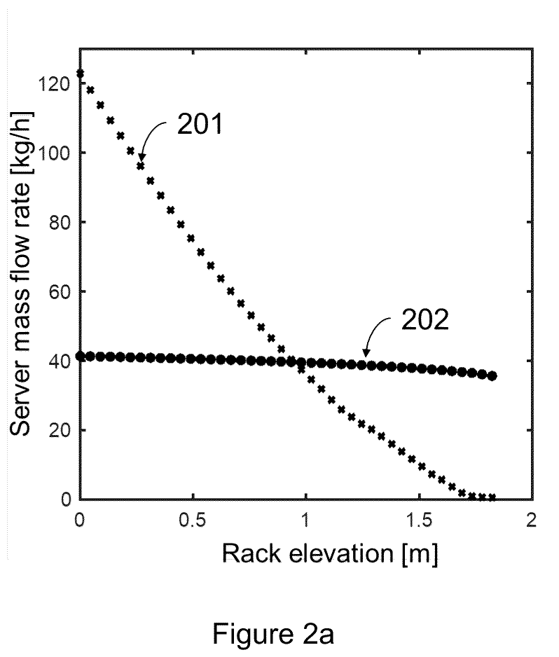

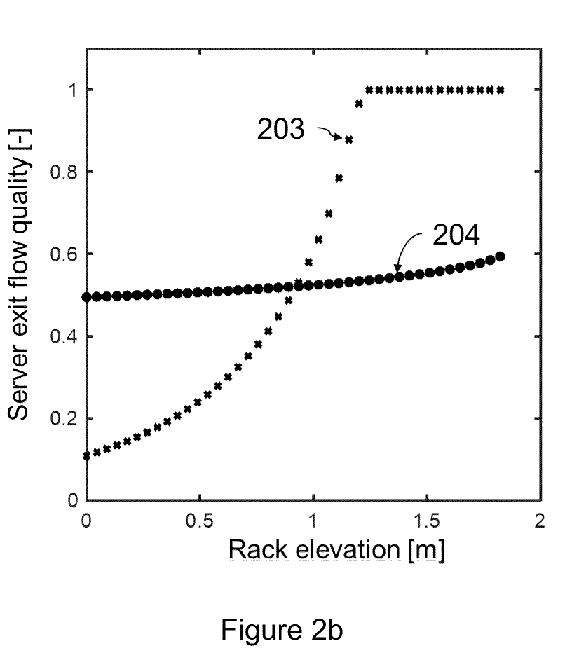

FIG. 2a shows a summary of data for a two-phase rack cooling system's flow distribution characteristic in terms of individual server mass flow rate before and after implementing CFCVs at the server level.

FIG. 2b shows a summary of data for a two-phase rack cooling system's flow distribution characteristic in terms of individual server exit flow quality before and after implementing CFCVs at the server level.

FIGS. 2a and 2b shows results of a liquid cooling loop implementation demonstrating the advantage of incorporating CFCV devices to control the flow of coolant into each level of a server rack in terms of server mass flow rate and exit quality, respectively. In this scenario, liquid coolant is fed to a rack manifold from an elevated condenser and distributed to the cold plate loops inside the servers where it undergoes partial boiling and returns to the condenser as a two-phase mixture.

Without any control (201 & 203), the static pressure gradient between the liquid supply and the two-phase mixture return results in more flow through the bottom servers in the rack and leaves the upper servers with little or no flow (201). Correspondingly, the flow quality is low for the bottom server and reaches full vapor conditions at the top of the rack (203).

The situation is distinctly different when CFCV devices are added at the entrance of each server on the cold plate loop liquid supply line. The parameters of the CFCV are defined to allow a design mass flow rate despite the static pressure gradient along the elevation of the rack, cabinet, or any other mounting structure. In this case, the mass flow distribution to each server cold plate loop is substantially more uniform (202) resulting in a more uniform exit flow quality (204).

Correspondingly, the vapor quality at the exit of each server cold plate loop is more uniform and, importantly, all cold plate loops receive sufficient flow to avoid dry-out and achieve uniform cooling of the IT hardware components (e.g., CPUs, GPUs, etc.).

A key advantage of implementing a CFCV on the server side is that the design mass flow can be defined based on the TDP of the server components being cooled well in advance of the server being deployed. Thus, in multi-server networks with servers having different TDPs (and mass flow requirements), the CFCV for each server is already tuned to constrain the flow based on specific TDP (thermal design power) of each server. This facilitates flexible deployment of the servers at any location within the rack without the need to perform manual flow balancing during the initial server rack integration or during field upgrades.

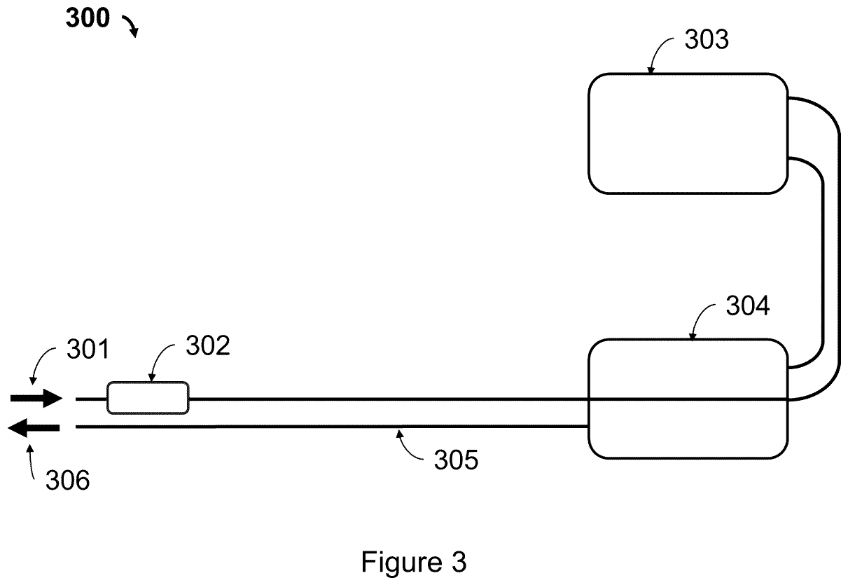

FIG. 3 shows a schematic of a dual socket cold plate loop (CPL) implementation with an inline CPL CFCV in a serial flow configuration (300). Liquid flows (301) into the CPL from the manifold at a rate controlled by an inline constant flow control valve (302). The design flow rate is determined by the TDP of the devices to be cooled to ensure that excessive flow is not distributed to the cold plates (303 & 304).

In the two-phase cooling system, it is advantageous for the CFCV to be located on the single-phase liquid supply side and not on the two-phase return side (305) as the pressure drop characteristics of the two-phase flow (306) are highly dependent on the flow's vapor quality.

In this configuration, the CFCV can be located anywhere on the liquid line from the entrance to the server cold plate loop to the inlet of the first cold plate. Note, that for a single-phase cooling system, this issue is not present and the CFCV can be located either on the supply or the return side of the cold plate loop.

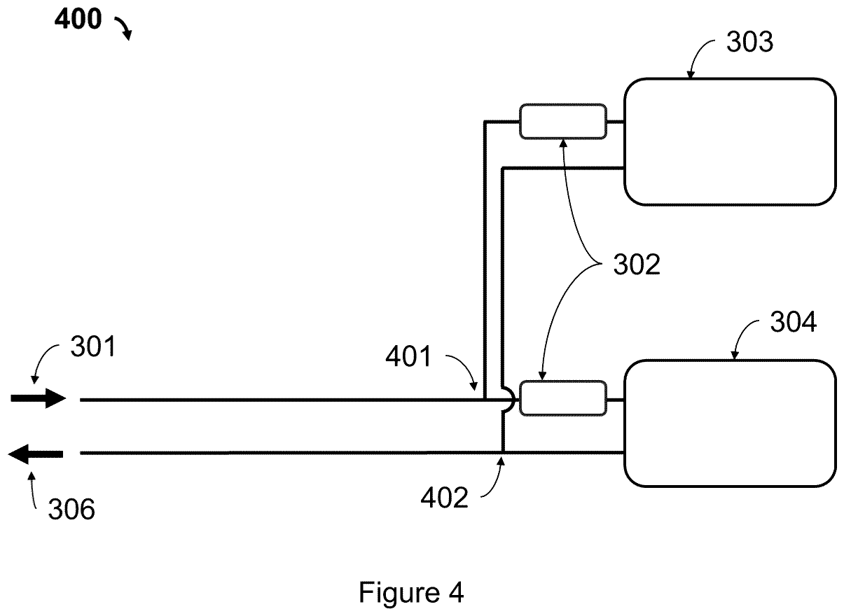

FIG. 4 shows a schematic of a dual socket cold plate loop (CPL) implementation with two inline CPL CFCV's in a parallel flow configuration (400). Liquid flows (301) into the CPL from the manifold at a rate controlled by two inline CFCVs (302). The design flow rate is determined by the TDP (thermal design power) of the devices to be cooled to ensure that excessive flow is not distributed to the two cold plates (303 & 304).

In this configuration, the CFCV can be located anywhere on the liquid line from the branch point (401) to the inlet of the cold plate. The two-phase mixture from each cold plate recombines (402) and returns from the CPL to the manifold (306).

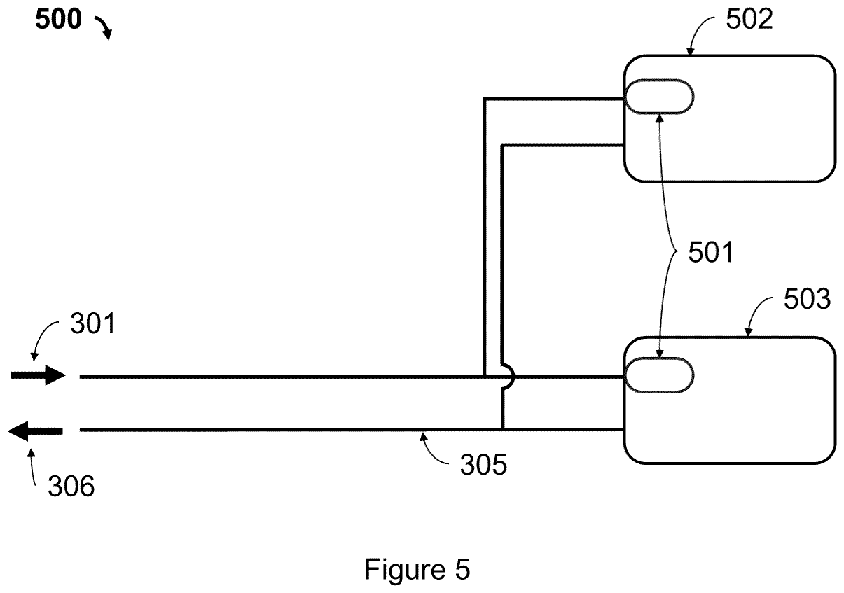

FIG. 5 shows a schematic of a dual socket cold plate loop (CPL) implementation in a parallel flow configuration with CFCVs integrated in the liquid supply ports of the cold plate (500). Liquid flows (301) into the CPL from the manifold at a rate controlled by two integrated constant flow control valves (501).

The design flow rate is determined by the TDP (thermal design power) of the devices to be cooled to ensure that excessive flow is not distributed to the two cold plates (502 & 503). The integration of the CFCV with the cold plate component can provide a space saving advantage in designing the CPL for the server environment it will be deployed in.

An additional benefit is the ability to accommodate processor families with a range of defined TDPs by matching the CFCV characteristic curve to the cooling requirements of a particular processor to avoid overcooling and maximize system efficiency. The two-phase mixture flows along the return line (305) from the cold plates and exits the CPL to enter the manifold (306).

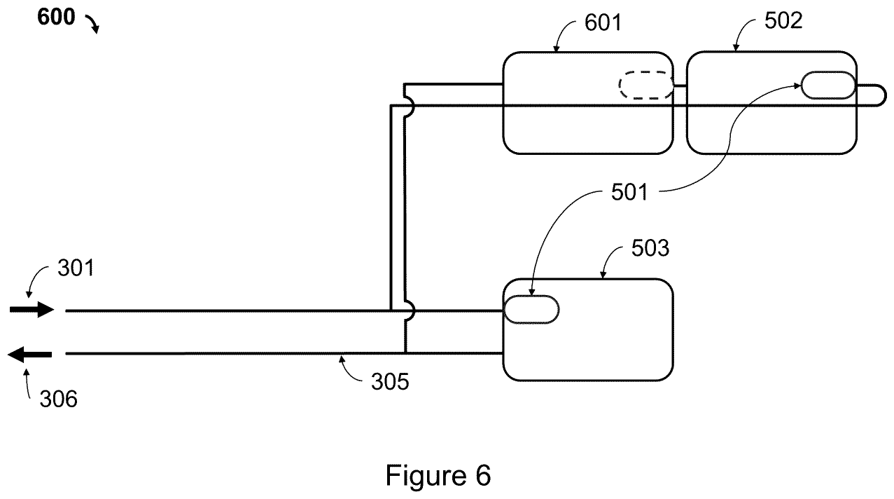

FIG. 6 shows a schematic of a cold plate loop (CPL) implementation in a hybrid serial/parallel flow configuration with CFCVs integrated in only the cold plates whose inlets are fed by the liquid supply line (600). Liquid flows (301) into the CPL from the manifold at a rate controlled by two integrated constant flow control valves (501) located after the branch point of the parallel flow.

The design flow rate is determined by the TDP of the devices to be cooled to ensure that excessive flow is not distributed to the cold plates configured in series (502 & 601) or the cold plate in parallel (503). The second cold plate in the serial leg of the CPL (601) is configured without the CFCV element such that the total required flow for the two cold plates is determined by the first cold plate in the serial leg (502). The two-phase mixture flows along the return line (305) from the cold plates and exits the CPL to enter the manifold (306).

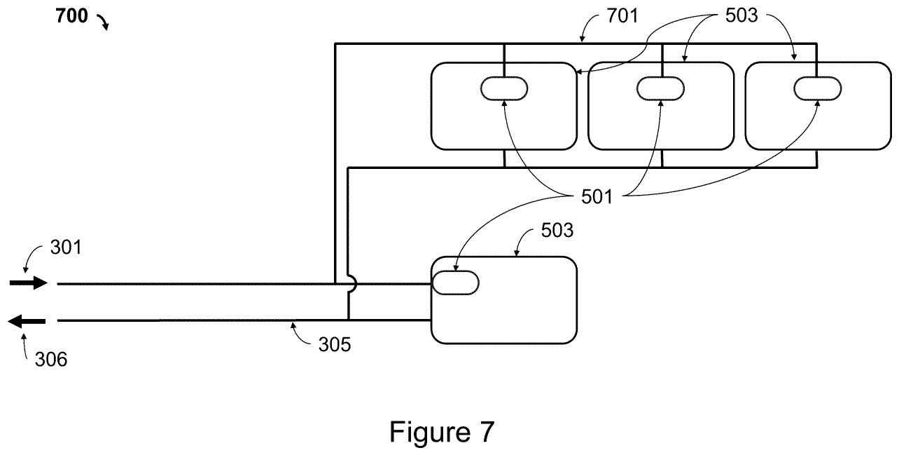

FIG. 7 shows a schematic of a cold plate loop (CPL) implementation in an arbitrary parallel flow configuration with CFCVs integrated in the cold plate (700). Liquid flows (301) into the CPL from the manifold at a rate controlled by the integrated constant flow control valves (501).

Multiple cold plates are fed by a local parallel flow distribution manifold (701). The design flow rate is determined by the TDP of each device to be cooled to ensure that excessive flow is not distributed to the cold plates (503). The location of the CFCVs in the cold plates facilitates the convenient layout of the connecting lines inside the server without the need to develop a customized design to ensure a balanced flow. The two-phase mixture flows along the return line (305) from the cold plates and exits the CPL to enter the manifold (306).

The integration of the CFCV with the cold plate is subject to the geometric design constraints imposed by the server architecture, e.g., height, number of heat sources to be cooled, etc. Thus, compact, space saving designs are advantageous.

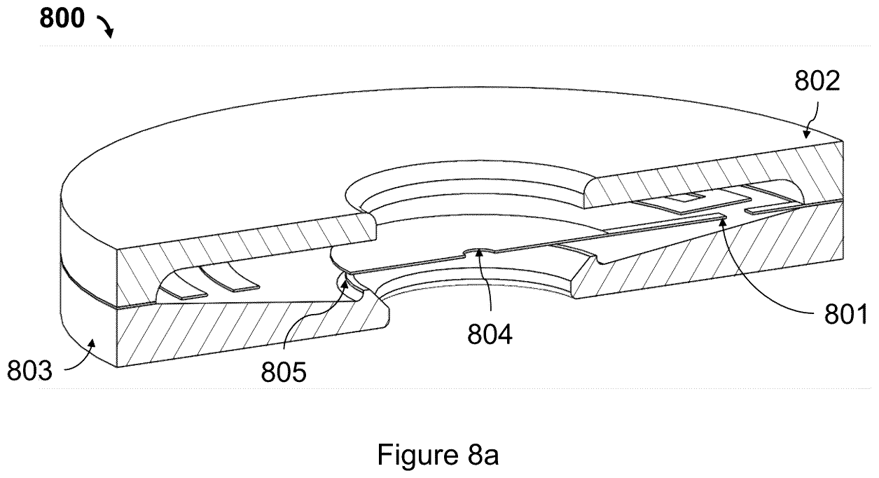

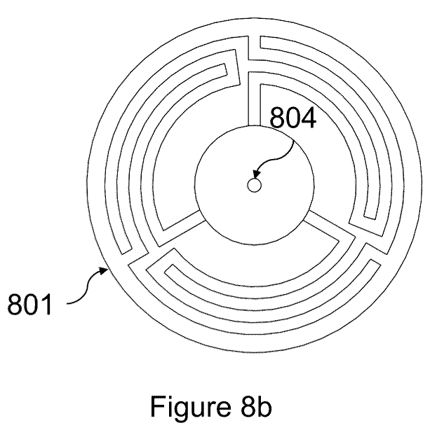

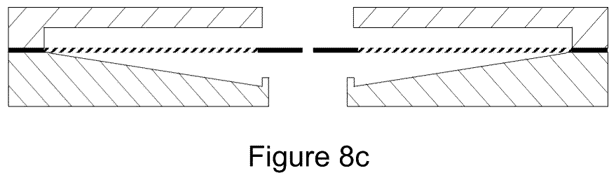

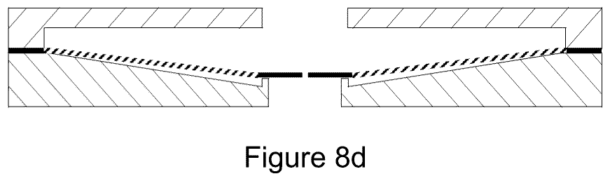

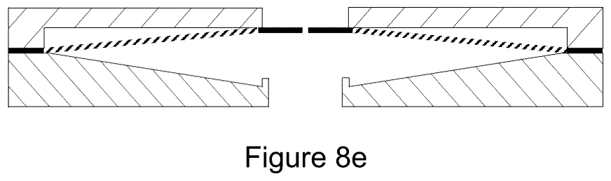

FIG. 8a shows a schematic of an ortho-planar spring orifice plate CFCV embodiment (800). A linear low stiffness ortho-planar spring with a central platform (FIG. 8b) defines the variable orifice. The geometry of this element is designed to achieve an appropriate spring stiffness. To achieve the design control flow, this element interfaces mechanically with a support structure (803) that progressively enhances the effective stiffness of the spring structure in the forward flow direction to tailor the displacement of the variable orifice to achieve the design mass flow rate over a wide dynamic range of pressure drop across the valve.

The low stiffness ortho-planar spring can readily be displaced due to an adverse pressure gradient to interface with a supporting structure (802) that seals or mostly seals against reverse flow.

A sprung orifice plate (801) is positioned between two bodies (802 & 803) to define a flow control valve that ensures mass flow in the forward flow direction to a design value within a pressure drop range of Δp⁻ to Δp⁺ and checks the flow in the reverse flow direction to a degree determined by the fixed orifice dimensions (804). In the no-flow state (FIG. 8c), the sprung orifice plate rests in an equilibrium position with the valve fully open.

FIG. 8b shows a schematic of an embodiment of an ortho-planar spring orifice plate embodiment.

FIG. 8c shows a schematic of an embodiment of an ortho-planar spring orifice plate CFCV design in the equilibrium position.

In the forward flow direction (FIG. 8d), an increasing pressure drop across the CFCV induces an increasing force on the sprung orifice plate leading to a deflection which progressively closes the gap between the orifice plate and the bottom insert (807). In the fully closed position at Δp Δp⁺, the valve Cv becomes constant and is defined by the fixed orifice dimensions (804).

The ideal force-displacement curve to maintain the design mass flow rate in the range of Δp⁻ to Δp⁺ is controlled by the design of the orifice plate spring and the guiding geometry of the bottom body (803).

FIG. 8d shows a schematic of an embodiment of an ortho-planar spring orifice plate CFCV design in the maximum forward flow position.

FIG. 8e shows a schematic of an embodiment of an ortho-planar spring orifice plate CFCV design in the maximum reverse flow position.

In the reverse flow direction (FIG. 8e), an adverse pressure gradient across the flow control valve induces a force on the sprung orifice plate leading to a deflection which closes the gap between the orifice plate and the top insert. In the fully closed position at Δp-Δp⁻, the valve Cv becomes constant and is defined by the fixed orifice characteristics. The spring displacement is unsupported by the top body to allow the valve to close with a minimum amount of adverse pressure gradient.

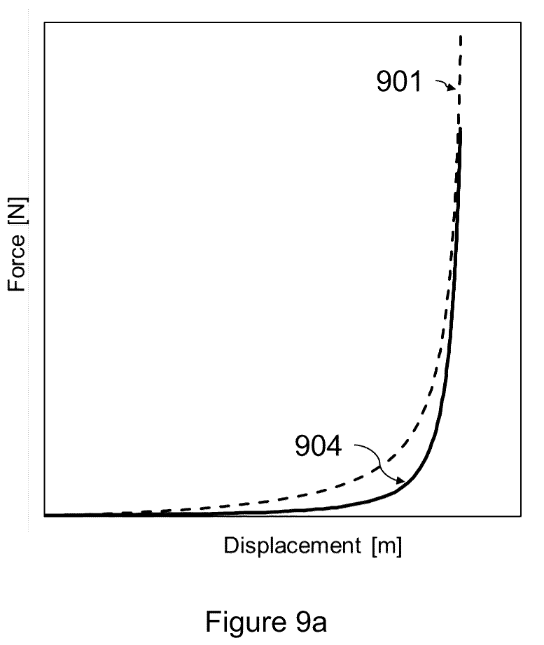

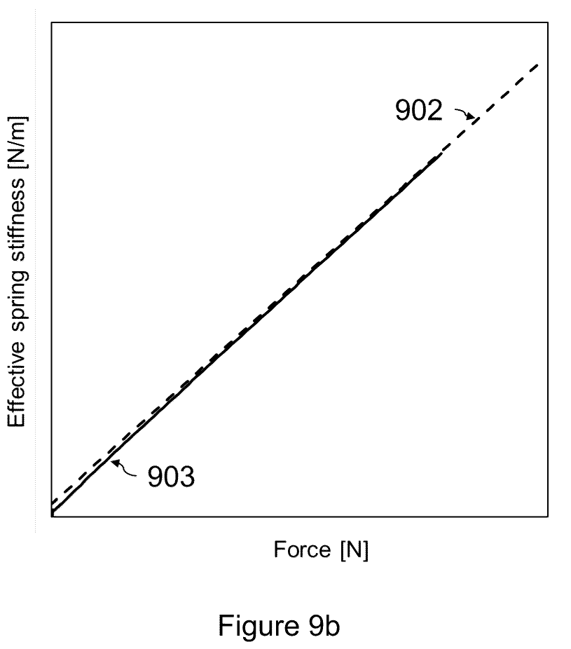

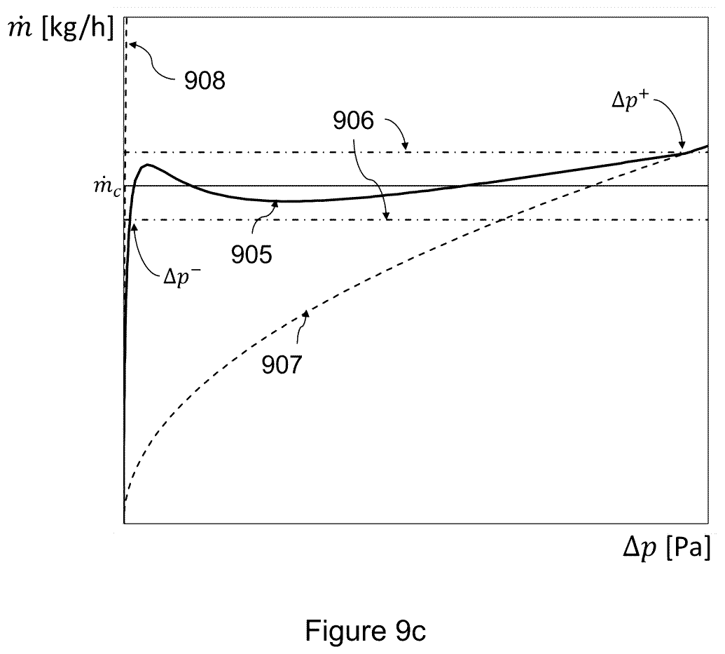

FIG. 9a, FIG. 9b and FIG. 9c shows an ortho-planar spring orifice plate CFCV design flow response.

A flow model is used to determine the ideal spring force-displacement response (901) shown in FIG. 9a and effective spring stiffness (902) shown in FIG. 9b to achieve control mass flow rate \dot{m}_{c} over the Δp⁻−Δp⁺ control range shown in FIG. 9c.

Fitting a simple linearly increasing stiffness as a function of applied force (903) yields the displacement curve (904) and the mass flow rate behavior (905) within an acceptable bound (906) of mₑ determined by the specific application, e.g., ±10%, and provides design guidance for the shape of the spring supporting structure (803). Beyond Δp⁺, the mass flow rate tends to the curve defined by the fixed orifice (907). In the limit as Δp→0 or without the flow control element installed, the Cv is characteristically large (908).

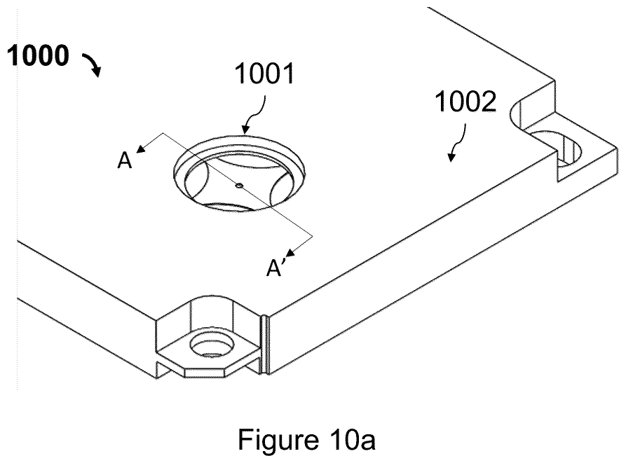

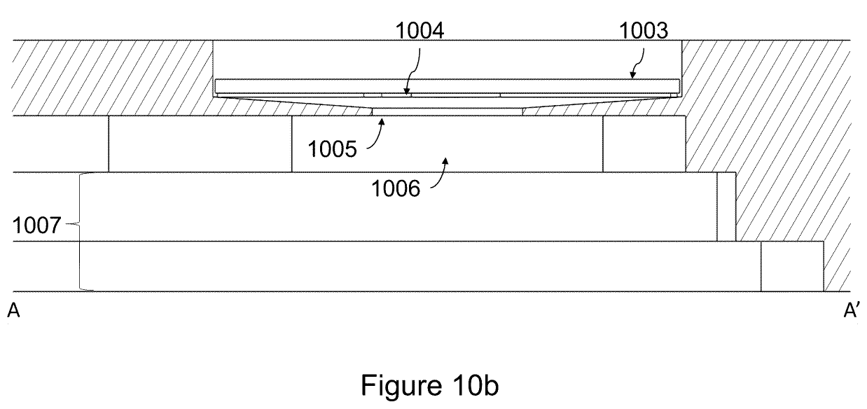

FIG. 10a shows a schematic of the CFCV incorporated into the cold plate cover (1000). A recess (1001) is defined in the cover plate (1002) to form the housing of the CFCV elements.

As shown in the cross-section schematic (FIG. 10b), a retaining ring (1003) confines the deformable element (1004) next to the shaped recess (1005) that opens into the cold plate manifold (1006) that sits above the recess for the cold plate heat transfer base (1007).

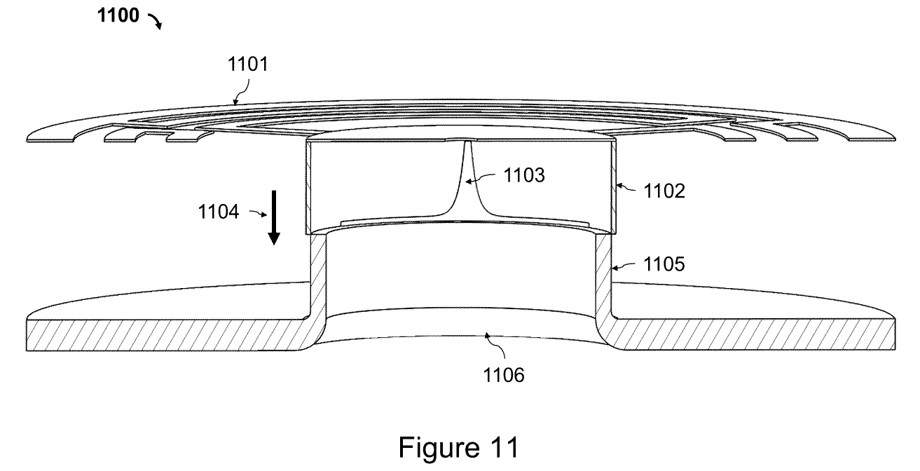

FIG. 11 shows a schematic of a compact variable flow area CFCV embodiment (1100).

To achieve the design mass flow rate over a wide dynamic range of pressure drop across the valve, a linear ortho-planar spring (1101) with a central platform supports a cylindrical body (1102).

To achieve the design mass flow rate as the pressure differential across the valve changes, the cylindrical body has an opening which defines the variable orifice flow area (1103) with a profile that changes in a non-linear fashion in the displacement vector (1104) with respect to a fixed concentric cylinder (1105) that admits flow to the cold plate inlet manifold (1106). This element can be paired with an additional low stiffness ortho-planar spring that can readily be displaced due to an adverse pressure gradient to interface with a supporting structure that seals or mostly seals against reverse flow to perform a check valve function.

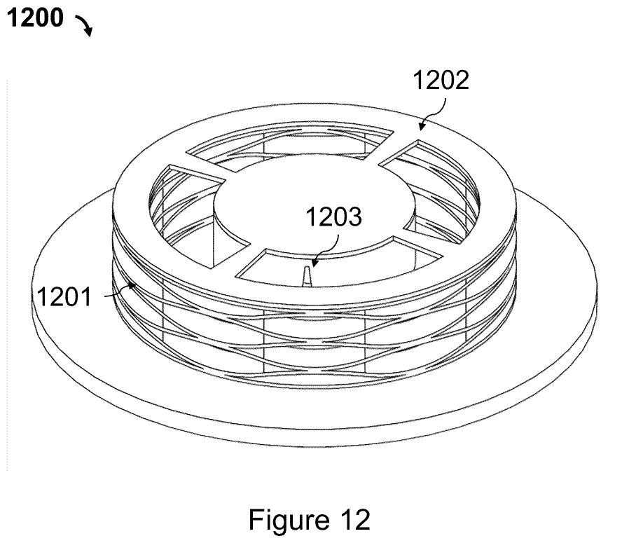

FIG. 12 shows a schematic of an additional embodiment of a compact variable flow area CFCV (1200). To achieve the design mass flow rate over a wide dynamic range of pressure drop across the valve, a linear compression wave spring (1201) is coupled with a central platform supporting a cylindrical body (1202).

The cylindrical body has an opening that defines the variable orifice flow area (1203) with a profile that changes in a non-linear fashion in the displacement vector (1104) with respect to a fixed concentric cylinder (1105) that leads to the cold plate inlet manifold (1106) to achieve the design mass flow rate as the pressure differential across the valve changes.

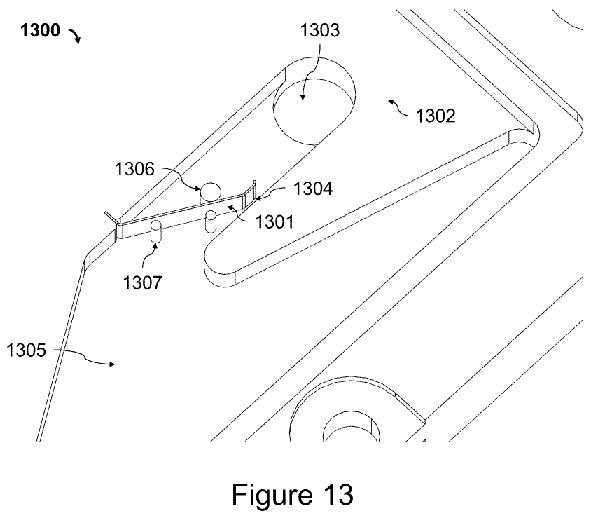

FIG. 13 shows a schematic of an embodiment of a spring cantilever-based CFCV integrated into the cold plate cover (1300).

A linear cantilever spring (1301) is installed in the liquid inlet manifold of the cover plate (1302) to define the variable orifice flow area. Liquid entering the cold plate through the inlet port (1303) flows substantially through the restricting gap between the cantilever and the cover plate (1304) into the lower pressure side of the liquid manifold (1305) leading to the heat transfer section.

The cantilever may be installed in a pre-loaded configuration by providing a support structure (1306) such that the spring only begins to displace as the lower control pressure differential across the valve is reached. Additional support structures (1307) can be defined such that the effective stiffness of the cantilever changes as the cantilever contacts those features during deflection to tailor the mass flow response.

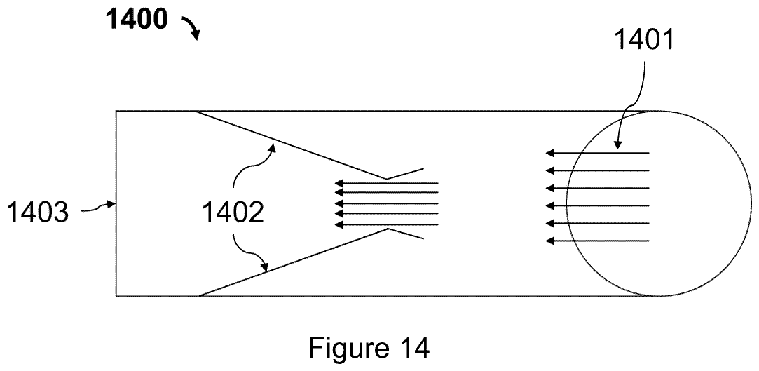

FIG. 14 shows a schematic of an embodiment of a double spring cantilever-based flow control valve integrated into the cold plate cover (1400). In this implementation, two cantilever springs, with similar or dissimilar force-displacement characteristics, define the variable orifice flow area. The liquid flow entering the cold plate (1401) passes substantially between the opening defined by the two cantilever structures before flowing towards the heat transfer section (1403).

The implementation of two cantilevers provides an additional degree of freedom in designing the mass flow response behavior of the CFCV.

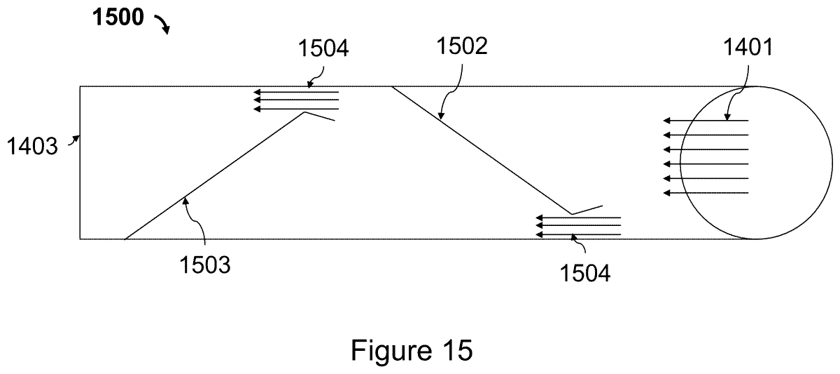

FIG. 15 shows a schematic of a two-stage cantilever spring for flow control that manages the risk of cavitation in the control region (1500). Liquid entering the cold plate (1401) may be saturated or only slightly sub-cooled.

To avoid the risk of cavitation where the local flow velocity is highest corresponding to a low static pressure region (1504), a multi-stage CFCV can be implemented with a high-pressure stage defined by a first cantilever-based valve (1502) and a lower pressure stage defined by a second cantilever-based valve (1503).

The characteristics of the valve can be defined such that the flow through the valve regions does not cavitate or that cavitation is significantly suppressed and enters the heat transfer section (1403) in the liquid or mostly liquid phase.

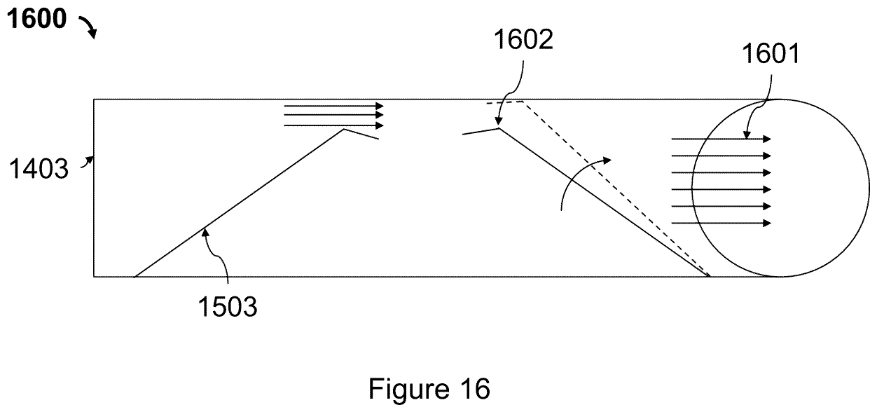

FIG. 16 shows a schematic of a cantilever spring for flow control and low stiffness cantilever spring check valve (1600). Under a reversed pressure gradient, flow now exits the cold plate through the inlet port (1601) due to, for example, a flow instability in the heat transfer section (1403) that forces the flow control spring (1503) open.

An additional cantilever spring (1602) can be implemented, that is open during normal operation, but can be readily displaced due to an reverse pressure gradient to interface with a supporting structure that seals or mostly seals against reverse flow to perform a check valve function.

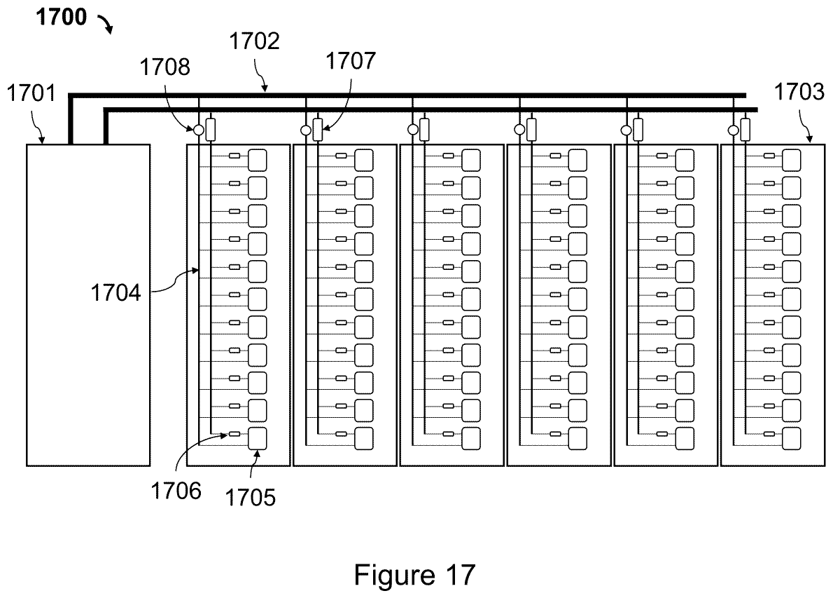

FIG. 17 shows a schematic of a centralized pumped coolant distribution unit (CDU) supplying multiple racks with coolant implementing rack-scale CFCVs as safety devices on the rack liquid supply line (1700).

The rack-level CFCV flow profile is characterized by (105) in FIG. 1 to prevent over supply of coolant in the event of a local CFCV failure in the rack or a major leak in the rack. This is complimented by a non-return valve (1708) on the return side such that in the event of a major leak, the rack will be isolated from the CDU cooling loop (1702) to prevent loss of all coolant from the CDU loop.

The pumped CDU (1701) distributes fluid via an overhead manifold (1702) to multiple racks (1703). Liquid coolant from the CDU manifold is distributed to the rack servers via a rack manifold (1704).

Each server has local CFCVs (1706) installed to manage the distribution of fluid to the heat generating components (1705) such as, but not limited to, CPUs, GPUs, NICs, DPUs, and other high-power components typically installed in servers or other packaged hardware devices.

A rack-scale CFCV (1707) is provided on the liquid supply line that prevents the over-supply of fluid that may arise due to a failure of one or more local CFCVs at the server level or due to a fluid leak inside the rack.

The flow pressure behavior is designed such that when Δp⁺ is reached the CFCV closes and seals to prevent the flow of fluid (105). The rack-level-CFCV is complemented with a sealing check valve on the fluid return line (1708) that closes due to a major leak of refrigerant in the rack.

The combination of the rack-level CFCV (1707) and the sealing check valve (1708) prevents loss of all coolant in the CDU distribution loop in the event of a major leak within one or more racks.

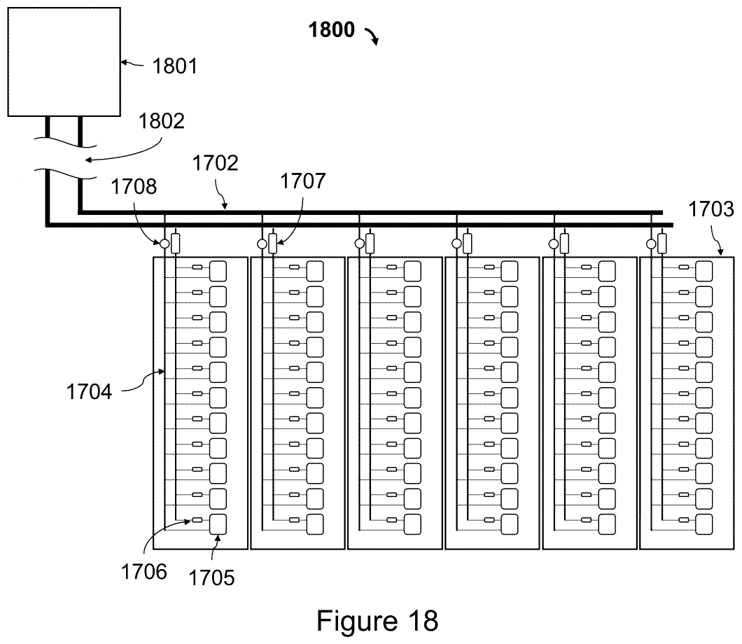

FIG. 18 shows a schematic of a centralized passive coolant distribution unit (CDU) supplying multiple racks with coolant implementing rack-scale CFCVs as safety devices on the rack liquid supply line (1800).

The passive CDU distributes fluid to the racks from an overhead position at a distance (1802) defined by the requirements of the application, e.g., externally mounted on a roof or wall, internally mounted on a ceiling or internal wall.

For example, the CDU (1801) may be an air-cooled condenser deployed on the roof of a facility. In this scenario, the rack-scale CFCV (1707) also manages excess static pressure downstream of the CFCV.

The term “approximately”/“approximate” can be +/−10% of the amount referenced. Additionally, preferred amounts and ranges can include the amounts and ranges referenced without the prefix of being approximately.

Although specific advantages have been enumerated above, various embodiments may include some, none, or all of the enumerated advantages.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps.

Additionally, steps may be performed in any suitable order. As used in this document, “each” refers to each member of a set or each member of a subset of a set.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

While the invention has been described, disclosed, illustrated and shown in various terms of certain embodiments or modifications which it has presumed in practice, the scope of the invention is not intended to be, nor should it be deemed to be, limited thereby and such other modifications or embodiments as may be suggested by the teachings herein are particularly reserved especially as they fall within the breadth and scope of the claims here appended.

We claim:

1. A multi heat source liquid cooling network system for cooling hardware components in server racks for information and communications technology (ICT) comprising:
a cold plate hat transfer section;
a flow distribution manifold; and
constant flow control valves (CFCVs) located between the cold plate heat transfer section and the flow distribution manifold, wherein the system provides for cooling the hardware components in the server racks for information and communications technology (ICT).

2. The system in claim 1, further comprising:
a multi heat source single-phase liquid cooling network wherein the CFCVs are located one of either a supply side or a return side between the cold plate and the flow distribution manifold.

3. The system in claim 1, further comprising:
a multi heat source two-phase liquid cooling network where the CFCVs are located on a supply side between a cold plate heat transfer section and the flow distribution manifold.

4. The system in claim 1, wherein the CFCVs are located on a side selected from the group consisting of: a pluggable unit side, a server side, a coolant supply side, and a coolant return side.

5. The system in claim 4, wherein the CFCVs are separate devices installed inline with tubing, and are located on the side selected from the group consisting of the pluggable unit side, the server side, the coolant supply side, and a coolant return side tubing.

6. System in claim 4, the CFCVs are integrated with a cold plate fitting, and integrated into at least one of the coolant supply side or coolant return side fitting connecting the cold plate to the return side tubing.

7. The system in claim 4, wherein the CFCVs are integrated into at least one of a body of the cold plate on the coolant supply side or in the coolant return side.

8. The system of claim 4, further comprising,
a flow control valve compatible with the system, wherein the flow control valve is installed in a liquid cooling loop operating with a fluid, selected from the group consisting water, water and glycol mixture, refrigerants and ammonia.

9. A multi heat source liquid cooling network system for cooling hardware components in server racks for information and communications technology (ICT) comprising:
a cold plates with a cold plate heat transfer section;
a flow distribution manifold; and
constant flow control valves (CFCVs) located between the cold plate heat transfer section and the flow distribution manifold, wherein at least one of the CFCVs is implemented to limit the mass flow rate of working fluid to the cold plates in a pluggable unit to a constant or substantially constant level, with a specific mass flow rate for each pluggable unit in a multi-unit network selected individually based on heat dissipating component's thermal design power (TDP) irrespective of the actual dissipated power at any point in time, at a maximum design dissipated power, of heat sources to be cooled that is defined by either
$$\dot{m} = \frac{TDP}{{C}_{p} Δ T}$$
for single-phase heat transfer where Cₚ is the specific heat capacity of the liquid and ΔT is the maximum design temperature rise of the liquid between supply and return side of the cold plates; or
$$\dot{m} = \frac{TDP}{{h}_{lv} Δ x}$$
for two-phase heat transfer where hₗᵥ is the coolant latent heat of vaporization and Δx is the maximum design flow quality change between the supply and return side of the cold plate(s), The system in claim 9, wherein at least one CFCV is selected to operate in a wide range of differential pressures across at least one of the return valves, specifically to achieve the design mass flow rate at a minimum pressure differential and to maintain the control mass flow rate up to a pressure differential comparable to the maximum pump head or static gravitational head driving the flow in the liquid cooling system.

10. The system of claim 1, wherein at least one of the CFCVs is comprised of:
a linear ortho-planar spring with a central platform which defines a variable orifice which interfaces mechanically with a support structure that progressively enhances effective stiffness of a spring structure to tailor displacement of the variable orifice to achieve a control flow rate.

11. The system of claim 11, wherein the ortho-planar spring is readily displaced in counter-flow direction due to an reverse pressure gradient to interface with a supporting structure that seals or mostly seals against reverse flow.

12. The system of claim 1, wherein at least one of the CFCVs is comprised of:
a linear ortho-planar spring or a low-profile linear wave spring with a central platform supporting a cylindrical body which defines the variable orifice flow area with a profile that changes in a non-linear fashion in the displacement vector to achieve the design mass flow rate as the pressure differential across the valve changes.

13. The system of claim 12, further comprising:
an additional ortho-planar spring that is readily displaced due to a reverse pressure gradient to interface with a supporting structure that seals or mostly seals against reverse flow.

14. The system of claim 1, wherein at least one of the CFCVs is comprised of:
a compact CFCV comprised of one or more linear cantilever springs mounted in an internal recess of the cold plate flow path that defines the variable orifice flow area with a stiffness profile that changes in a non-linear fashion in the displacement vector due to supporting structures to achieve the selected mass flow rate as pressure differential across the valve changes, Installed in a pre-loaded configuration such that the spring begins to displace as the lower control pressure differential across the valve is reached.

15. The system in claim 14, further comprising:
additional cantilever springs that are readily displaced due to an adverse pressure gradient to interface with a supporting structure that seals or mostly seals against reverse flow.

16. The system in claim 1, further comprising:
a flow control valve constructed of elastic material, wherein a fluidic path is restricted due to deformation of fluidic path cross section caused by a pressure differential; wherein deformation is selected from the group consisting of: elongation, shrinkage, and distortion; wherein fully deformed fluidic path will define maximum mass flow rate through the control valve.

17. The system of claim 1, for multi-server networks with heat dissipating components having different TDPs (thermal design powers), the CFCV controlling flow for each heat dissipating component are tuned individually to constrain the flow at different flow rates based on specific TDP (thermal design power) of each heat dissipating component.

18. The system of claim 1, further comprising:
Rack-level CFCVs on a liquid supply side of a rack manifold for a case of a centralized CDU (coolant distribution unit), either pumped or passive, feeding multiple racks, which prevent oversupply of coolant to one or more racks in event of a local CFCV failure in the rack or an oversupply of pressure from the CDU.

19. The system of claim 1, wherein rack-level CFCVs installed on a liquid supply side of the rack manifold for a centralized CDU feeding multiple racks, which shut off flow once an upper pressure differential across a return valve has been reached, and are paired with a shut-off non-return valve on the return side to prevent complete loss of coolant in the event of a major leak at the rack level.
